(19) United States
(12) Patent Application Publication
(10) Pub. No.: US 2025/0202508 A1
(43) Pub. Date: Jun. 19, 2025

(54) COMPUTER SYSTEM AND METHOD FOR ARITHMETIC DECODING

(71) Applicant: STMicroelectronics International N.V., Geneva (CH)

(72) Inventor: Min XUE, Seyssinet-Pariset (FR)

(73) Assignee: STMicroelectronics International N.V., Geneva (CH)

(21) Appl. No.: 18/977,678

(22) Filed: Dec. 11, 2024

(30) Foreign Application Priority Data
Dec. 19, 2023 (FR) 2314483

(51) Int. Cl. H03M 13/00; H03M 13/39

(52) U.S. Cl. CPC H03M 13/6561; H03M 13/3994

(57) ABSTRACT

A computer system for performing arithmetic decoding includes one or more memories configured to store an array of coefficients and an interval of values. The computer system includes a circuit configured to perform comparisons of the coefficients of the array of coefficients and the interval of values and count the results of the comparisons that are identical and successive. The computer system also includes a digital signal processor configured to determine a value of a symbol associated with the array of coefficients based on the count of identical and successive results.

### BACKGROUND

### Technical Field

Embodiments and implementations relate to arithmetic decoding.

### Description of the Related Art

Arithmetic coding is a data compression technique commonly used in computing and signal processing. Unlike traditional binary coding, where each symbol is represented by a fixed number of bits, arithmetic coding allows representing symbols using fractions of intervals of real numbers.

Arithmetic coding has the advantage of being able to compress data efficiently according to the probability of the symbols. The most frequent symbols will occupy smaller fractions of the interval, whereas the least frequent symbols will occupy larger fractions, thereby enabling a more efficient compression of the data.

In particular, arithmetic coding is used by the “LC3” (standing for “Low Complexity Communication Codec” in English) audio encoder-decoder. Arithmetic coding is then used to compress audio data and then arithmetic decoding is used to recover the original audio data from the compressed representation.

In particular, arithmetic coding implements different steps. Firstly, probabilities are assigned to the symbols. In particular, before coding begins, each symbol in the message is assigned to a probability. The probabilities may be based on statistics of frequencies of apparition of the symbols in the message.

Afterwards, an initial interval is defined at the beginning of the coding process. The message is then scrolled symbol-by-symbol. At each step, the current interval is divided into sub-intervals, the size of which is proportional to the probabilities of the symbols. The sub-interval corresponding to the symbol currently being processed is selected to represent this symbol. The current interval then becomes the selected sub-interval.

Once all the symbols have been encoded, the binary representation of the real number in the final interval is extracted. This binary representation is the compressed message.

Once the message has been compressed by arithmetic coding, it is possible to recover the original message by arithmetic decoding, reversing the steps implemented during arithmetic coding.

In particular, arithmetic decoding comprises an initialization of the initial interval used during coding on the basis of the probabilities associated with the symbols.

Once the initial interval has been reconstructed, the iterative decoding of the symbols can begin. The decoder starts to read the bits of the binary representation of the compressed message one-by-one, and at each step, it re-adjusts the interval according to the sequence of bits read. It should take into account the probabilities associated with the symbols to determine which sub-interval corresponds to the symbol being decoded.

With each iteration, the decoder compares the current interval with the sub-intervals corresponding to each possible symbol. When a sub-interval corresponds to the current interval, the decoder identifies the symbol associated with that sub-interval as the decoded symbol.

More particularly, with each iteration, a comparison is carried out between the interval start value and a value calculated by a multiplication between the length of the interval and a coefficient. Each coefficient corresponds to a value associated with a symbol. The sequence of tests is performed until obtaining a comparison result corresponding to a test validity condition. To decode a symbol, the number of tests performed is a value comprised between 1 and the number of possible symbols.

### BRIEF SUMMARY

Known methods for carrying out an arithmetic decoding require performing branches at each iteration. These numerous branches increase the time required to perform the arithmetic decoding. Thus, such an arithmetic decoding is not very efficient.

Hence, there is a need to propose a solution that allows carrying out an arithmetic decoding more quickly.

In some embodiments, a computer system is proposed comprising: a data memory configured to store an array of coefficients, a digital signal processor configured to execute a computer program comprising instructions allowing carrying out an arithmetic decoding on the basis of said array of coefficients and an interval of values, and a circuit configured to: perform comparisons on the basis of the coefficients of said array of coefficients and of said interval of values, and count the results of said comparisons which are identical and successive, the digital signal processor being configured to determine a value of a symbol associated with said array of coefficients from the number of said identical and successive results counted by said dedicated circuit.

Using a circuit dedicated to arithmetic decoding integrated into said digital signal processor allows accelerating the arithmetic decoding, by reducing the number of cycles of said digital signal processor to carry out the arithmetic decoding. In this way, it is also possible to reduce the power consumption to perform an arithmetic decoding. Furthermore, the fact of first performing all of the comparisons associated with each of the coefficients in the table before calculating the value of the symbol avoids having to perform numerous branches in comparison with known solutions.

In some embodiments, the dedicated circuit comprises a first block configured to calculate a comparison variable allowing storing the results of said comparisons, the result of each comparison corresponding to a bit of the comparison variable.

In some embodiments, the first block is configured to carry out in parallel at least two comparisons on the basis of at least two successive coefficients of the array of coefficients with the interval of values.

Thus, in such a computer system, the fact that all of the comparisons associated with each of the coefficients in the array are performed initially before calculating the value of the symbol enables the comparisons to be done in parallel. Hence, this allows accelerating the arithmetic decoding.

In some embodiments, the first block comprises at least two parallel branches allowing performing said two comparisons simultaneously, each branch including: a multiplier circuit configured to perform a multiplication between a coefficient amongst said two successive coefficients and a length of said interval of values shifted by a given number of bits, this given number of bits being in particular comprised between 0 and a number of bits used to define the length of said interval (for example said given number of bits is equal to 10), and a comparator circuit configured to compare a result of the multiplication with a start value of the interval of values.

In some embodiments, the first block further comprises a circuit for updating the comparison variable configured to integrate into said comparison variable the results of the comparison performed by each comparator circuit.

In some embodiments, the dedicated circuit also comprises a second block configured to implement a state machine configured to count the successive identical results stored in said comparison variable by analyzing the bits of said comparison variable.

In some embodiments, the results of each comparison performed by the first block are stored progressively on the right in the comparison variable. The state machine implemented by the second block is then configured to count the number of identical comparison results from the rightmost bits in the comparison variable.

In some embodiments, the results of each comparison performed by the first block are stored progressively on the left in the comparison variable. The state machine implemented by the second block is then configured to count the number of identical comparison results from the leftmost bits in the comparison variable.

In some embodiments, said computer program comprises instructions which, when they are executed by the digital signal processor, cause the latter to: implement the first block in order to perform in parallel a comparison from each coefficient of said coefficient array with said interval, the result of each comparison being stored in the comparison variable, then implement the second block, once all of the comparisons have been performed, to count the successive identical results stored in said comparison variable by analyzing the bits of said comparison variable, then calculate a value of the symbol associated with said array of coefficients from the number of successive identical results counted.

In some embodiments, a method implemented by a computer system is proposed, the method comprising: executing, by a digital signal processor of the computer system, a computer program comprising instructions allowing carrying out an arithmetic decoding on the basis of an array of coefficients stored in a data memory of the computer system and an interval of values, the arithmetic decoding including: implementing a circuit of the computer system dedicated to said arithmetic decoding to: perform comparisons on the basis of the coefficients of said array of coefficients and of said interval of values, then count the results of said comparisons which are identical and successive, then determining by the digital signal processor a value of a symbol associated with said array of coefficients from the number of said identical and successive results counted by said dedicated circuit.

In some embodiments, the implementation of said dedicated circuit comprises an implementation of a first block of the dedicated circuit for calculating a comparison variable allowing storing the results of said comparisons, the result of each comparison corresponding to a bit of the comparison variable.

In some embodiments, the implementation of the first block is adapted to carry out in parallel at least two comparisons from at least two successive coefficients of the array of coefficients with the interval of values.

In some embodiments, the implementation of the first block comprises an implementation of at least two parallel branches adapted to perform said two comparisons simultaneously, the implementation of each branch including: implementing a multiplier circuit for performing a multiplication between a coefficient amongst said two successive coefficients and a length of said interval of values shifted by a given number of bits, this given number of bits being in particular comprised between 0 and a number of bits used to define the length of said interval, implementing a comparator circuit for comparing a result of the multiplication with a start value of the interval of values.

In some embodiments, the implementation of the first block further comprises an implementation of a circuit for updating the comparison variable to integrate into said comparison variable the results of the comparison performed by each comparator circuit.

In some embodiments, the implementation of the dedicated circuit also comprises an implementation of a second block for executing a state machine adapted to count the successive identical results stored in said comparison variable by analyzing the bits of said comparison variable.

In some embodiments, the results of each comparison performed by the first block are stored progressively on the right in the comparison variable. The state machine implemented by the second block is then adapted to count the number of identical comparison results from the rightmost bits in the comparison variable.

In some embodiments, the results of each comparison performed by the first block are stored progressively on the left in the comparison variable. The state machine implemented by the second block is then adapted to count the number of identical comparison results from the leftmost bits in the comparison variable.

In some embodiments, the execution of said computer program leads to: implementing the first block in order to perform in parallel a comparison from each coefficient of said array of coefficients with said interval, the result of each comparison being stored in the comparison variable, then implementing the second block, once all of the comparisons have been performed, to count the successive identical results stored in said comparison variable by analyzing the bits of said comparison variable, then calculating by the digital signal processor a value of the symbol associated with said array of coefficients on the basis of the number of successive identical results counted.

### BRIEF DESCRIPTION OF THE SEVERAL VIEWS OF THE DRAWINGS

Other advantages and features of the disclosure will become apparent upon reading the detailed description of embodiments, which are in no way limiting, and from the appended drawings wherein:

FIG. 1 is a block diagram illustrating a computer system for arithmetic decoding in some embodiments.

FIG. 2 is a logic circuit diagram illustrating logic to perform comparisons of two consecutive values of an array of coefficients to a range of values in parallel in some embodiments.

FIG. 3 is a block diagram illustrating logic to count trailing zero bits of a comparison variable in some embodiments.

FIG. 4 is a block diagram illustrating logic to determine a value of a symbol based on a coefficient array associated with the symbol in some embodiments.

FIG. 5 is a block diagram illustrating a computer system for arithmetic decoding in some embodiments.

FIG. 6 is a logic circuit diagram illustrating logic to perform comparisons of two consecutive values of an array of coefficients to a range of values in parallel in some embodiments.

FIG. 7 is a block diagram illustrating logic to count leading zero bits of a comparison variable in some embodiments.

FIG. 8 is a block diagram illustrating logic to determine a value of a symbol based on a coefficient array associated with the symbol in some embodiments.

FIG. 9 is a table diagram illustrating contents of an array of coefficients associated with a symbol in some embodiments.

### DETAILED DESCRIPTION

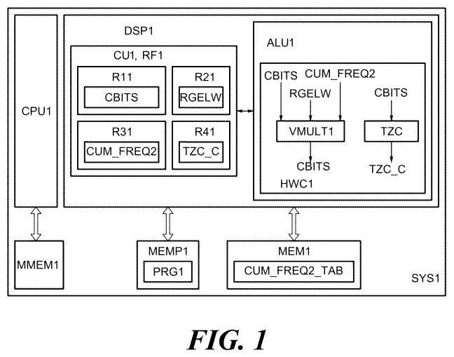

FIG. 1 illustrates a first embodiment of a computer system SYS1. The computer system SYS1 comprises a central processing unit CPU1, a main memory MMEM1 and a digital signal processor DSP1 (also referred to by the English expression “Digital signal processor”) with a data memory MEM1 and a program memory MEMP1. The DSP1 comprises a control unit CU1 with a data register file RF1 (also referred to by the English expression “Control Unit and Register File”) and an arithmetic and logic unit ALU1 (also referred to by the English expression “Arithmetic and Logic Unit”). The arithmetic logic unit ALU1 comprises a circuit HWC1 dedicated to the acceleration of the arithmetic decoding. The computer system SYS1 may be a system-on-chip.

The digital signal processor DSP1 is configured to execute a computer program PRG1 comprising instructions allowing carrying out an arithmetic decoding.

This computer program PRG1 may be stored in the program memory MEMP1 of the computer system SYS1.

The digital signal processor DSP1 comprises a first register R11 configured to store a variable CBITS containing the comparison results.

The digital signal processor DSP1 also comprises a second register R21 configured to store a value interval length RGE and a value LW of the start of this interval of values. The length RGE and the value LW may be concatenated into one single binary word RGELW in the second register R21.

The digital signal processor DSP1 also comprises a third register R31 configured to store two concatenated coefficients.

The digital signal processor DSP1 also comprises a fourth register R41 configured to store a right zero bit counter TZC_C.

In particular, the circuit HWC1 may be obtained from an “RTL” (standing for “Register Transfer Level” in English) code.

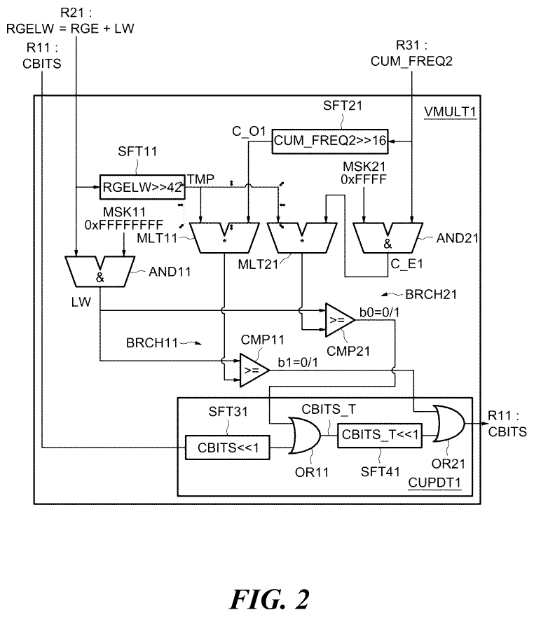

The dedicated circuit HWC1 comprises a first block VMULT1 configured to perform calculations and tests vectorially (i.e., in parallel) during arithmetic decoding. The first block VMULT1 is illustrated in FIG. 2.

In particular, the first block VMULT1 is configured to receive as input the variable CBITS stored in the first register R11. The first block VMULT1 is also configured to receive as input the word RGELW stored in the second register R21 including the interval length RGE and the interval start value LW. The interval length RGE and the value LW can be concatenated in the same word received as input. The first block VMULT1 is also configured to receive as input the two concatenated coefficients CUM_FREQ2.

The first block VMULT1 comprises a first shift circuit SFT11. This first shift circuit SFT11 is configured to receive the word RGELW comprising the interval length RGE and the concatenated value LW. This first shift circuit is configured to shift this word 42 bits to the right. This allows outputting the 32 bits associated with the interval start value LW and then shifting the value of the interval length RGE 10 bits to the right in order to obtain a temporary value TMP.

The first block VMULT1 also comprises an “AND” type first logic gate AND11. This first “AND” type logic gate AND11 is configured to receive the word RGELW comprising the concatenated interval length RGE and value LW as well as a first mask MSK11 with a hexadecimal value ‘0xFFFFFFFF’. This first “AND” type logic gate AND11 allows applying the first mask MSK11 to said word RGELW received as input so as to recover the interval start value LW.

The first block VMULT1 also comprises a second shift circuit SFT21. This second shift circuit SFT21 is configured to receive the two concatenated coefficients CUM_FREQ2 and to shift these two concatenated coefficients CUM_FREQ2 16 bits to the right so as to keep only the odd coefficient C_O1.

The first block VMULT1 further comprises a second “AND” type logic gate AND21. This second “AND” type logic gate AND21 is configured to receive the two concatenated coefficients CUM_FREQ2 as well as a second mask MSK21 with the hexadecimal value ‘0xFFFF’. This second “AND” type logic gate AND21 allows applying the second mask MSK21 to said value CIM_FREQ2 so as to recover the even coefficient C_E1.

The first block VMULT1 also comprises two parallel branches BRCH11, BRCH21. A first branch BRCH11 comprises a first multiplier circuit MLT11 and a first comparator circuit CMP11. The second branch BRCH21 comprises a second multiplier circuit MLT21 and a second comparator circuit CMP21. The two branches BRCH11, BRCH21 allow performing two multiplications in parallel, and then two comparison tests based on the two different coefficients C_O1 and C_E1 derived from the two concatenated coefficients CUM_FREQ2.

In particular, the first multiplier circuit MLT11 is configured to receive as input the temporary value TMP generated at the output of the first shift circuit SFT11 and the odd coefficient C_O1. The first multiplier circuit MLT11 is then configured to multiply said temporary value TMP with the odd coefficient C_O1.

The second multiplier circuit MLT21 is configured to receive as input the temporary value TMP generated at the output of the first shift circuit SFT11 and the even coefficient C_E1. The second multiplier circuit MLT21 is then configured to multiply said temporary value TMP with the even coefficient C_E1.

The first comparator circuit CMP11 is configured to receive the result of the multiplication carried out by the first multiplier circuit MLT11 and the interval start value LW. The first comparator circuit CMP11 is then configured to compare the result of said multiplication with the interval start value LW in order to know whether said interval start value LW is greater than or equal to the result of said multiplication. If said value LW is greater than or equal to the result of said multiplication, then the first comparator circuit CMP11 generates a comparison bit b1 equal to 1. If said value LW is less than the result of said multiplication, then the first comparator circuit CMP11 generates a comparison bit b1 equal to 0.

The second comparator circuit CMP21 is configured to receive the result of the multiplication carried out by the second multiplier circuit MLT21 as well as the interval start value LW. The second comparator circuit CMP21 is then configured to compare the result of said multiplication with the interval start value LW in order to know whether said interval start value LW is greater than or equal to the result of said multiplication. If said value LW is greater than or equal to the result of said multiplication, then the first comparator circuit CMP21 generates a comparison bit b0 equal to 1. If said value LW is less than the result of said multiplication, then the first comparator circuit CMP21 generates a comparison bit b0 equal to 0.

The first block VMULT1 also comprises a circuit CUPDT1 for updating the variable CBITS. The circuit CUPDT1 for updating the variable CBITS allows integrating the comparison bits b1 and b0 to the right of the old variable CBITS received as input from the first block VMULT1.

In particular, the update circuit CUPDT1 comprises a third shift circuit SFT31 configured to shift the variable CBITS received as input from the first block VMULT1 one bit to the left.

The update circuit CUPDT1 also comprises a first “OR” type logic gate OR11 configured to carry out an “OR” type operation between the variable CBITS shifted by one bit and the comparison bit b0. Thus, the first “OR” type logic gate OR11 allows integrating the comparison bit b0 into the variable CBITS. This allows obtaining a temporary CIBTS variable CBITS_T.

The update circuit CUPDT1 also comprises a fourth shift circuit SFT41 configured to shift the temporary variable CBITS_T integrating the comparison bit b0 one bit to the left.

The update circuit CUPDT1 also comprises a second “OR” type logic gate OR21 configured to carry out an “OR” type operation between the comparison bit b1 and the temporary variable CBITS_T integrating the comparison bit b0. Thus, the second “OR” type logic gate OR21 allows integrating the comparison bit b1 into the temporary variable CBITS_T. This allows obtaining an updated variable CBITS integrating the comparison bits b0 and b1 to the right of the variable CBITS. Afterwards, the new variable CBITS may be stored in the register R11 of the digital signal processor DSP1.

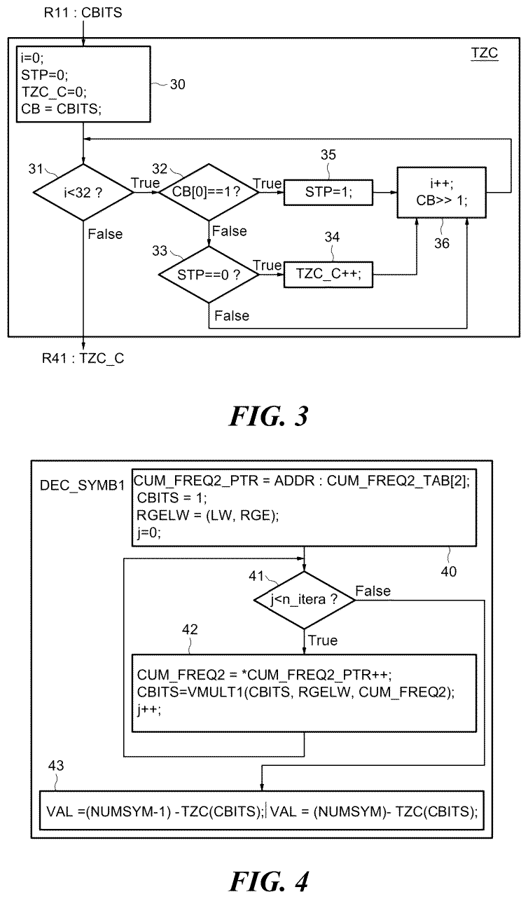

The dedicated circuit HWC1 comprises a second block TZC configured to receive the variable CBITS stored in the first register R11. The second block TZC is configured to implement a state machine allowing executing a process of counting a number of zero bits to the right in the variable CBITS. Such a method is illustrated in FIG. 3.

The counting method comprises an initialization step 30. The initialization step 30 allows initializing an index i at 0, a stop variable STP at 0, a zero bit counter TZC_C at 0, and a variable CB at the value of the variable CBITS.

Afterwards, the counting method comprises a first comparison step 31. This first comparison step 31 is adapted to compare whether the value of the index i is less than 32.

If the value of the index i is less than 32, then the method then comprises a second comparison step 32. This second comparison step 32 is adapted to compare whether the value of the least significant bit CB[0] of the variable CB (i.e., the rightmost bit in the variable CB) is equal to 1.

If the value of the least significant bit CB[0] of the variable CB is different from 1, in particular equal to 0, then the method then comprises a third comparison step 33. This third comparison step 33 is adapted to compare whether the stop variable STP is equal to 0.

If the stop variable STP is equal to 0, then the method comprises a step 34 of incrementing the zero bit counter TZC_C.

Afterwards, the method comprises a step 36 of incrementing the index i and shifting the variable CB. In this step 36, the value of the index i is incremented by 1 and the variable CB is shifted one bit to the right.

Afterwards, the method is reiterated from the first comparison step 31.

If the value of the least significant bit CB[0] of the variable CB is equal to 1 in step 32, then the method comprises a step 35 of updating the stop variable STP. In this step 35, the stop value STP is set at 1. Afterwards, the method resumes with said step 36 of incrementing the index i and shifting the variable CB.

If the value of the stop variable STP is different than 0, in particular equal to 1, in step 33, then the method resumes at step 36 of incrementing the index i and shifting the variable CB.

If the value of the index i is equal to 32 in step 31, then the value of the zero bit counter is written to the register R41.

As seen before, the digital signal processor DSP1 is configured to execute a computer program PRG1 comprising instructions which allow carrying out an arithmetic decoding. In particular, the execution of said instructions cause the digital signal processor DSP1 to execute a function DEC_SYMB1. This function DEC_SYMB1 is illustrated in FIG. 4.

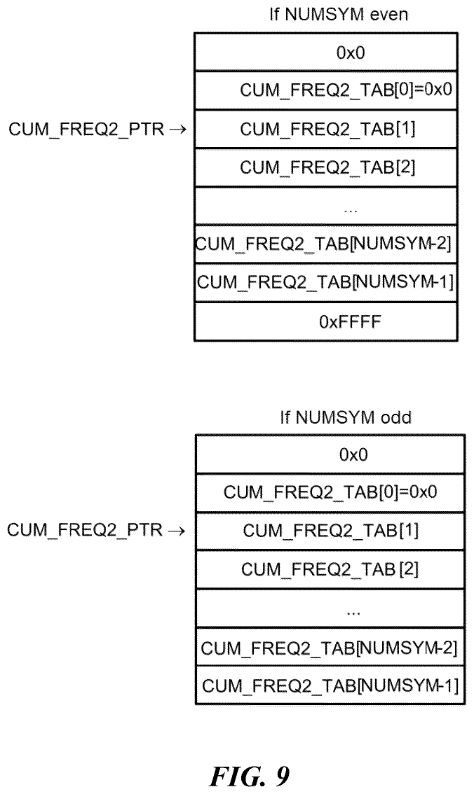

This function DEC_SYMB1 is configured to determine the value of a symbol from a coefficient array CUM_FREQ2_TAB[] associated with this symbol and stored in the data memory MEM1 of the digital signal processor DSP1. In order to align each vector of two 16-bit elements of this 32-bit array, the array is organized according to the parity of the number of symbols NUMSYM as shown in FIG. 9. A zero element is inserted at the beginning of each array. When NUMSYM is even, an additional element with a hexadecimal value of 0xFFFF is added at the end of the array.

More particularly, the decoding method comprises an initialization step 40 before determining the value of the symbol from the coefficient array CUM_FREQ2_TAB[].

In this step 40, the pointer CUM_FREQ2_PTR is initialized to point to the address of the coefficient array CUM_FREQ2_TAB[2]. Furthermore, the variable CBITS is initialized at 1. The length RGE of the range of values and the interval start value LW are concatenated in the same word RGELW stored in the register R11. An index j is defined as 0.

Once the initialization is complete, the value of the symbol can be decoded using the following method.

Said method comprises a test step in which the index j is compared with the number of iterations n_itera to be performed. In particular, the number of iterations n_itera to be performed depends on the number of possible symbols.

If the number of possible symbols is odd, then the number of iterations to be performed is calculated by the following formula:
n_itera=(NUMSYM−1)/2, where n_itera is the number of iterations to be performed and numsym is the number of possible symbols.

If the number of possible symbols is even, then the number of iterations to be performed is calculated by the following formula:
n_itera=NUMSYM/2, where n_itera is the number of iterations to be performed and numsym is the number of possible symbols.

If the index j is less than the number of iterations n_itera to be performed, then the method comprises a step 42 allowing performing multiplications and comparisons in parallel from two coefficients of the array of coefficients.

Step 42 comprises reading a pair of coefficients and then updating the pointer CUM_FREQ2_PTR to point to the coefficient following the two read coefficients.

Afterwards, step 42 comprises calculating a new value CBITS by implementing the first block VMULT1 of the circuit HWC1. In particular, the first block VMULT1 is implemented by taking as input the current value CBITS, the word RGELW and the two coefficients CUM_FREQ2 previously read.

The first block VMULT1 is used to perform a multiplication between the coefficients CUM_FREQ2 read and the value RGE of the interval length shifted 10 bits to the right, and then the comparisons between the results of these multiplications and the value LW at the interval start. The results of these comparisons correspond to the comparison bits b0 and b1 which are integrated in the new variable CBITS.

Next, step 42 comprises incrementing the index j by 1.

Afterwards, the method resumes at step 41 so as to reiterate the operations implemented by the first block VMULT1 for each coefficient of the array CUM_FREQ[] until the index j reaches the number of increments to be performed.

When the index j reaches the number of increments to be performed in step 41, then the method comprises a step 43 of calculating the value VAL. In particular, this value VAL is calculated by implementing the second block TZC in order to determine the number of zeros to the right in the last variable CBITS calculated.

In particular, if the number of possible symbols is odd, then the value of the symbol is calculated by the formula:
VAL=(NUMSYM−1)−TZC(CBITS), where NUMSYM is an even number of possible symbols, TZC(CBITS) is the function implemented by the second block TZC from the variable CBITS.

If the number of possible symbols is even, then the value of the symbol is calculated by the formula:
VAL=NUMSYM−TZC(CBITS), where NUMSYM is an odd number of possible symbols, TZC(CBITS) is the function implemented by the second block TZC from the variable CBITS.

Afterwards, a symbol can be decoded from the value VAL calculated from the interval defined by the interval length RGE and the interval start value.

In such an arithmetic decoding method, the fact of first performing all of the comparisons associated with each of the coefficients of the array before calculating the value of the symbol enables the comparisons to be done in parallel. Hence, this allows accelerating the arithmetic decoding.

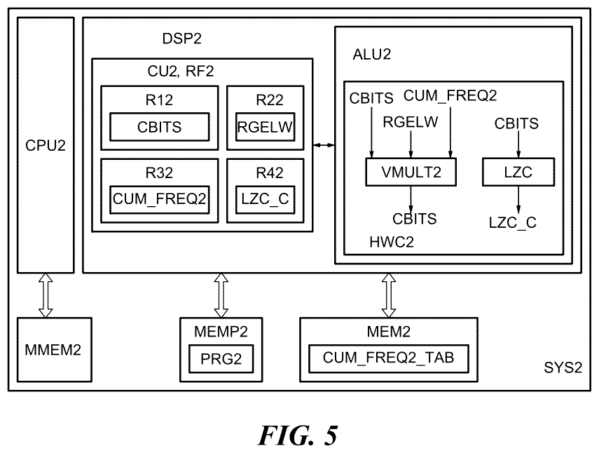

FIG. 5 illustrates a second embodiment of a computer system SYS2. The computer system SYS2 is similar to the computer system SYS1 of FIG. 1. In particular, the computer system SYS2 comprises a central processing unit CPU2, a main memory MMEM2 and a digital signal processor DSP2 (also referred to by the English expression “Digital signal processor”) with a data memory MEM2, a program memory MEMP2. The digital signal processor DSP2 comprises a control unit CU2 with a data register file RF2 (also referred to by the English expression “Control Unit and Register File”) and an arithmetic and logic unit ALU2 (also referred to by the English expression “Arithmetic and Logic Unit”). The arithmetic logic unit ALU2 comprises a circuit HWC2 dedicated to the acceleration of the arithmetic and integrated decoding. The computer system SYS2 may be a system-on-chip.

The digital signal processor DSP2 is configured to execute a computer program PRG2 comprising instructions allowing carrying out an arithmetic decoding. This computer program PRG2 may be stored in the program memory MEMP2 of the computer system SYS2.

The digital signal processor DSP2 comprises a first register R12 configured to store a comparison variable CBITS.

The digital signal processor DSP2 also comprises a second register R22 configured to store a value interval length RGE and a value LW of the start of this value interval. The length RGE and the value LW may be concatenated into one single binary word RGELW in the second register R22.

The digital signal processor DSP2 also comprises a third register R32 configured to store two concatenated coefficients CUM_FREQ2.

The digital signal processor DSP2 also comprises a fourth register R42 configured to store a left zero bit counter LZC_C in the variable CBITS.

In particular, the circuit HWC2 may be integrated into the digital signal processor DSP2. In particular, such a circuit HWC2 may be obtained from an “RTL” (standing for “Register Transfer Level” in English) code.

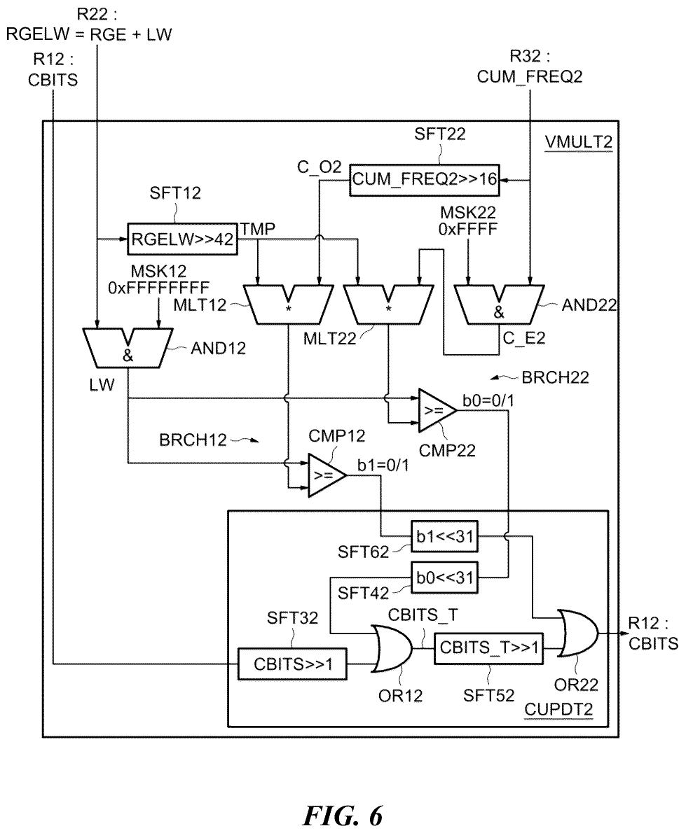

The dedicated circuit HWC2 comprises a first block VMULT2 configured to perform calculations and tests vectorially (i.e., in parallel) during arithmetic decoding. This first block VMULT2 is illustrated in FIG. 6.

In particular, the first block VMULT2 is configured to receive as input the variable CBITS stored in the first register R12. The first block VMULT2 is also configured to receive as input the value interval length RGE and the interval start value LW. The interval length RGE and the value LW may be concatenated in the same word RGELW stored in register R22. The first block VMULT2 is also configured to receive as input the two concatenated coefficients CUM_FREQ2.

The first block VMULT2 comprises a first shift circuit SFT12. This first shift circuit SFT12 is configured to receive the word RGELW comprising the interval length RGE and the concatenated value LW. This first shift circuit SFT12 is configured to shift this word 42 bits to the right. This allows outputting the 32 bits associated with the interval start value LW and then shifting the value of the interval length RGE 10 bits to the right in order to obtain a temporary value TMP.

The first block VMULT2 also comprises a first “AND” type logic gate AND12. This first “AND” type logic gate AND12 is configured to receive the word RGELW comprising the interval length RGE and the concatenated value LW as well as a first mask MSK12 with the hexadecimal value ‘0xFFFFFFFF’. This first “AND” type logic gate AND12 allows applying the first mask MSK12 to said word RGELW received as input so as to recover the interval start value LW.

The first block VMULT2 also comprises a second shift circuit SFT22. This second shift circuit SFT22 is configured to receive the two concatenated coefficients CUM_FREQ2 and to shift these two concatenated coefficients CUM_FREQ2 16 bits to the right so as to keep only the odd coefficient C_O2 of said two concatenated coefficients CUM_FREQ2.

The first block VMULT2 further comprises a second “AND” type logic gate AND22. This second “AND” type logic gate AND22 is configured to receive the two concatenated coefficients CUM_FREQ2 and a second mask with the hexadecimal value ‘0xFFFF’. This second “AND” type logic gate AND22 allows applying the second mask to the two concatenated coefficients CUM_FREQ2 so as to recover the even coefficient C_E2 of said two concatenated coefficients CUM_FREQ2.

The first block VMULT2 also comprises two parallel branches BRCH12 and BRCH22. A first branch BRCH12 comprises a first multiplier circuit MLT12 and a first comparator circuit CMP12. The second branch BRCH22 comprises a second multiplier circuit MLT22 and a second comparator circuit CMP22. The two branches BRCH12 and BRCH22 allow performing two multiplications in parallel and then two comparison tests using the two different coefficients C_O2, C_E2 derived from the two concatenated coefficients CUM_FREQ2.

In particular, the first multiplier circuit MLT12 is configured to receive as input the temporary value TMP generated at the output of the first shift circuit SFT12 and the odd coefficient C_O2. The first multiplier circuit MLT12 is then configured to multiply said temporary value TMP with the odd coefficient C_O2.

The second multiplier circuit MLT22 is configured to receive as input the temporary value TMP generated at the output of the first shift circuit SFT12 and the even coefficient C_E2. The second multiplier circuit MLT22 is then configured to multiply said temporary value TMP with the even coefficient C_E2.

The first comparator circuit CMP12 is configured to receive the result of the multiplication carried out by the first multiplier circuit MLT12 as well as the interval start value LW. The first comparator circuit CMP12 is then configured to compare the result of said multiplication with the interval start value LW in order to know whether said interval start value LW is greater than or equal to the result of said multiplication. If said value LW is greater than or equal to the result of said multiplication, then the first comparator circuit CMP12 generates a comparison bit b1 equal to 1. If said value LW is less than the result of said multiplication, then the first comparator circuit CMP12 generates a comparison bit b1 equal to 0.

The second comparator circuit CMP22 is configured to receive the result of the multiplication carried out by the second multiplier circuit MLT22 as well as the interval start value LW. The second comparator circuit CMP22 is then configured to compare the result of said multiplication with the interval start value LW in order to know whether said interval start value LW is greater than or equal to the result of said multiplication. If said value LW is greater than or equal to the result of said multiplication, then the first comparator circuit CMP22 generates a comparison bit b1 equal to 1. If said value LW is less than the result of said multiplication, then the first comparator circuit CMP22 generates a comparison bit b1 equal to 0.

The first block VMULT2 also comprises a circuit CUPDT2 for updating the variable CBITS. The circuit CUPDT2 for updating the variable CBITS allows integrating the comparison bits b1 and b0 to the right of the old variable CBITS received as input from the first block VMULT2.

In particular, the update circuit CUPDT2 comprises a third shift circuit SFT32 configured to shift the variable CBITS received as input one bit to the right.

The update circuit CUPDT2 comprises a fourth shift circuit SFT42 configured to shift the comparison bit b0 31 bits to the left.

The update circuit CUPDT2 also comprises a first “OR” type logic gate OR12 configured to carry out an “OR” type operation between the variable CBITS shifted by one bit and the shifted comparison bit b0. Thus, the first “OR” type logic gate OR12 allows integrating the comparison bit b0 on the left in the variable CBITS. This allows obtaining a temporary variable CBITS_T.

The update circuit CUPDT2 also comprises a fifth shift circuit SFT52 configured to shift the temporary variable CBITS_T integrating the comparison bit b0 one bit to the right.

The update circuit CUPDT2 comprises a sixth shift circuit SFT62 configured to shift the comparison bit b1 31 bits to the left.

The update circuit CUPDT2 also comprises an “OR” type second logic gate OR22 configured to carry out an “OR” type operation between the shifted comparison bit b1 and the temporary variable CBITS_T integrating the comparison bit b0 shifted one bit to the right. Thus, the second “OR” type logic gate OR22 allows integrating the comparison bit b1 on the left in the temporary variable CBITS_T. This allows obtaining an updated variable CBITS integrating the comparison bits b0 and b1 to the left of the variable CBITS. Afterwards, the new variable CBITS may be stored in the register R12 of the digital signal processor DSP2.

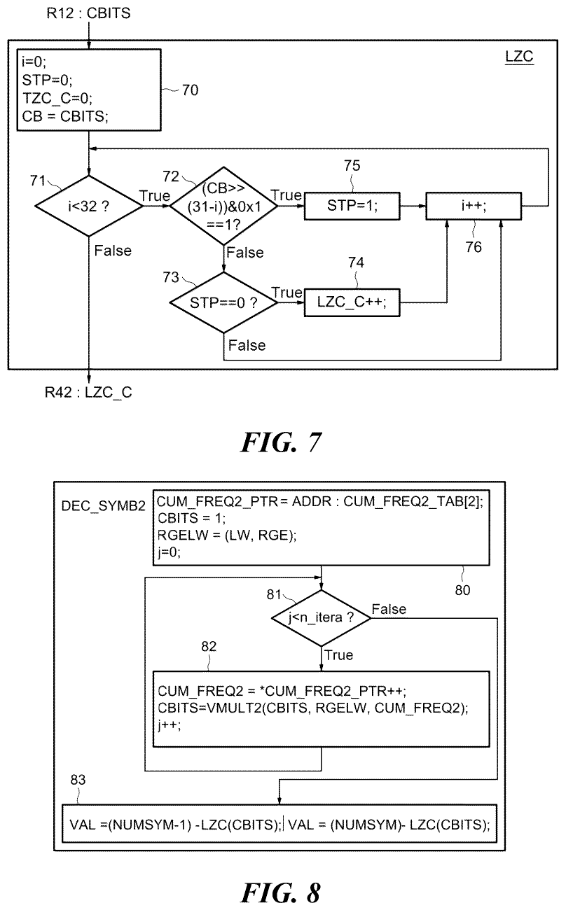

The dedicated circuit HWC2 comprises a second block LZC configured to receive the variable CBITS stored in the first register R12. The second block LZC is configured to implement a state machine allowing executing a process of counting a number of zeros to the left in the variable CBITS. Such a counting method is illustrated in FIG. 7.

The counting method comprises an initialization step 70. The initialization step 70 allows initializing an index i at 0, a stop variable STP at 0, a left zero bit counter LZC_C at 0, and a variable CB at the value of the variable CBITS.

Afterwards, the counting method comprises a first comparison step 71. This first comparison step 71 is adapted to compare whether the value of the index i is less than 32.

If the value of the index is less than 32, then the method then comprises a second comparison step 72. This second comparison step 72 is adapted to shift the variable CB by a number of bits equal to 31−i and then apply a mask with the hexadecimal value 0x1 to said shifted variable CB. The second comparison step 72 is also adapted to then compare whether the value obtained after application of the mask to the shifted variable CB is equal to 1.

If the value obtained after applying the mask to the shifted variable CB is different from 1, in particular equal to 0, then the method comprises a third comparison step 73 afterwards. This third comparison step 73 is adapted to compare whether the stop variable STP is equal to 0.

If the stop variable STP is equal to 0, then the method comprises a step 74 of incrementing the left zero bit counter LZC_C.

Afterwards, the method comprises a step 76 of incrementing the index i. In this step, the value of the index i is incremented by 1.

Afterwards, the method is reiterated from the first comparison step 71.

If the value obtained after application of the mask to the shifted variable CB is equal to 1 in step 72, then the method comprises a step 75 of updating the stop variable STP. In this step 75, the stop value is STP set at 1. Afterwards, the method resumes with said step 76 of incrementing the index i.

If the value of the stop variable STP is different from 0, in particular equal to 1, in step 73, then the method resumes with step 76 of incrementing the index i.

If the value of the index i is equal to 32 in step 71, then the value of the left zero bit counter LZC_C is stored in the register R42.

As seen before, the digital signal processor DSP2 is configured to execute a computer program PRG2 comprising instructions that allow carrying out an arithmetic decoding. In particular, the execution of said instructions cause the digital signal processor DSP2 to execute a function DEC_SYMB2. This function DEC_SYMB2 is illustrated in FIG. 8.

This function DEC_SYMB2 is configured to determine the value of a symbol from an array of coefficients CUM_FREQ2_TAB[] associated with this symbol and stored in the data memory MEM2 of the digital signal processor DSP2. In order to align each vector of 2 16-bit elements of this 32-bit array, this array is organized according to the parity of the number of symbols NUMSYM as shown in FIG. 9. A zero element is inserted at the beginning of each array. When NUMSYM is even, an additional element with a hexadecimal value 0xFFFF is added at the end of the array.

More particularly, the decoding method comprises an initialization step 80 before determining the value of the symbol from the array of coefficients CUM_FREQ2_TAB[].

In this step 80, the pointer CUM_FREQ2_PTR is initialized to point to the address of the array of coefficients CUM_FREQ2_TAB[2]. Furthermore, the variable CBITS is initialized at 1. The length RGE of the interval of values and the interval start value LW are concatenated in the same word RGELW. An index j is set at 0.

Once initialization is complete, the symbol can be decoded by the following method.

The method comprises a test step 81 in which the index j is compared with the number of iterations n_itera to be performed. In particular, the number of iterations n_itera to be performed depends on the number of possible symbols.

If the number of possible symbols is odd, then the number of iterations to be performed is calculated by the following formula:
n_itera=(numsym−1)/2, where n_itera is the number of iterations to be performed and numsym is the number of possible symbols.

If the number of possible symbols is even, then the number of iterations to be performed is calculated by the following formula:
n_itera=numsym/2, where n_itera is the number of iterations to be performed and numsym is the number of possible symbols.

If the index j is less than the number of iterations to be performed, then the method includes a step 82 allowing performing multiplications and comparisons in parallel on the basis of two coefficients from the array of coefficients.

Step 82 comprises updating the pointer CUM_FREQ2_PTR in order to point to the coefficient following the two coefficients read.

Afterwards, step 82 comprises calculating a new value CBITS by implementing the first block VMULT2 of the circuit HWC2. In particular, the first block is implemented by taking as input the current value CBITS, the word RGELW and the two coefficients CUM_FREQ2 previously read.

The implementation of the first block VMULT2 allows performing a multiplication between the coefficients read and the interval length value shifted 10 bits to the right, and then the comparisons between the results of these multiplications and the interval start value. The results of these comparisons correspond to the comparison bits b0 and b1 which are integrated in the new variable CBITS.

Step 82 then comprises a step of incrementing the index j. In this step, the index j is incremented by 1.

Afterwards, the method resumes at step 81 so as to repeat the operations implemented by the first block VMULT2 for each coefficient of the array CUM_FREQ[] until the index j reaches the number of increments to be performed.

When the index j reaches the number of increments to be performed in step 81, then the method comprises a step 83 of calculating the value VAL. In particular, this value VAL is calculated by implementing the second block LZC in order to determine the number of zeros to the right in the last variable CBITS calculated.

In particular, if the number of possible symbols is odd, then the value of the symbol is calculated by the formula:
VAL=(NUMSYM−1)−LZC(CBITS), where NUMSYM is an even number of possible symbols, LZC(CBITS) is the function implemented by the second block LZC from the variable CBITS.

If the number of possible symbols is even, then the value of the symbol is calculated by the formula:
VAL=NUMSYM−LZC(CBITS), where NUMSYM is an odd number of possible symbols, LZC(CBITS) is the function implemented by the second block LZC from the variable CBITS.

Afterwards, a symbol can be decoded from the value VAL calculated from the interval defined by the interval length RGE and the interval start value.

In such an arithmetic decoding method, the fact of first performing all of the comparisons associated with each of the coefficients of the array before calculating the value of the symbol enables the comparisons to be done in parallel. Hence, this allows accelerating the arithmetic decoding.

Of course, the embodiments are susceptible to various variants and modifications which will appear to the person skilled in the art. In particular, it is possible for the digital signal processor DSP2 to be configured to implement by itself the function carried out by the second block LZC. Thus, in this case, it is not necessary to provide for such a second block in the dedicated circuit. This then allows saving space in the computer system SYS2.

Furthermore, the first blocks VMULT1 and VMULT2 may respectively have more branches than the two branches BRCH11, BRCH21 and BRCH12, BRCH22 in order to perform a greater number of multiplications and comparisons at the same time in order to process all of the coefficients in the array of coefficients CUM_FREQ2_TAB[] more quickly.

The previously-described arithmetic decoding methods may be implemented in the context of decoding of an audio signal, normally for a decoder LC3. The symbols to be decoded then correspond to audio data.

A computer system may be summarized as including: a data memory (MEM) configured to store an array of coefficients (CUM_FREQ2_TAB[]), a digital signal processor (DSP1, DSP2) configured to execute a computer program (PRG1, PRG2) including instructions allowing carrying out an arithmetic decoding from said array of coefficients and an interval of values, a circuit (HWC1, HWC2) dedicated to said arithmetic decoding, this circuit being configured to: perform comparisons on the basis of the coefficients of said array of coefficients and of said interval of values, then count the results of said comparisons which are identical and successive, the digital signal processor (DSP1, DSP2) being configured to determine a value of a symbol associated with said array of coefficients from the number of said identical and successive results counted by said dedicated circuit.

The dedicated circuit (HCW1, HCW2) may include a first block (VMULT1, VMULT2) configured to calculate a comparison variable (CBITS) allowing storing the results of said comparisons, the result of each comparison corresponding to a bit of the comparison variable (CBITS).

The first block (VMULT1, VMULT2) may be configured to carry out in parallel at least two comparisons from at least two successive coefficients (C_O1, C_E1, C_O2, C_E2) of the array of coefficients with the range of values.

The first block (VMULT1, VMULT2) may include at least two parallel branches (BRCH11, BRCH21, BRCH12, BRCH22) allowing performing said two comparisons simultaneously, each branch including: a multiplier circuit (MLT11, MLT21, MLT12, MLT22) configured to perform a multiplication between a coefficient amongst said two successive coefficients (C_O1, C_E1, C_O2, C_E2) and a length (RGE) of said interval of values shifted by a given number of bits, this given number of bits being in particular between 0 and a number of bits used to define the length of said interval, a comparator circuit (CMP11, CMP21, CMP12, CMP22) configured to compare a result of the multiplication with a start value (LW) of the interval of values.

The first block may further include a circuit (CUPDT1, CUPDT2) for updating the comparison variable configured to integrate into said comparison variable (CBITS) the results of the comparison performed by each comparator circuit.

The dedicated circuit (HCW1, HCW2) may also include a second block (TZC, LZC) configured to implement a state machine configured to count the successive identical results stored in said comparison variable (CBITS) by analyzing the bits of said comparison variable (CBITS).

The results of each comparison performed by the first block (VMULT1) may be stored progressively on the right in the comparison variable (CBITS), and the state machine implemented by the second block (TZC) may be configured to count the number of identical comparison results from the rightmost bits in the comparison variable (CBITS).

The results of each comparison performed by the first block (VMULT2) may be stored progressively on the left in the comparison variable (CBITS), and the state machine implemented by the second block (LZC) may be configured to count the number of identical comparison results from the leftmost bits in the comparison variable (CBITS).

Said computer program (PRG1, PRG2) may include instructions which, when executed by the digital signal processor (DSP1, DSP2), cause the latter to: implement the first block (VMULT1, VMULT2) in order to perform in parallel a comparison from each coefficient of said array of coefficients with said interval, the result of each comparison being stored in the comparison variable (CBITS), then implement the second block (TZC, LZC), once all of the comparisons have been performed, to count the successive identical results stored in said comparison variable (CBITS) by analyzing the bits of said comparison variable (CBITS), and then—calculate a value (VAL) of the symbol associated with said array of coefficients from the number of successive identical results counted.

A method implemented by a computer system (SYS1, SYS2), the method may be summarized as including executing, by a digital signal processor (DSP1, DSP2) of the computer system (SYS1, SYS2), a computer program (PRG1, PRG2) including instructions allowing carrying out an arithmetic decoding from an array of coefficients stored in a data memory of the computer system (SYS1, SYS2) and an interval of values, the arithmetic decoding including: implementing a circuit (HWC1, HWC2) of the computer system dedicated to said arithmetic decoding to: perform comparisons on the basis of the coefficients of said array of coefficients and of said interval of values, then count the results of said comparisons which are identical and successive, then determining by the digital signal processor (DSP1, DSP2) a value of a symbol associated with said array of coefficients from the number of said identical and successive results counted by said dedicated circuit.

The implementation of said dedicated circuit (HCW1, HCW2) may include an implementation of a first block (VMULT1, VMULT2) of the dedicated circuit for calculating a comparison variable (CBITS) allowing storing the results of said comparisons, the result of each comparison corresponding to one bit of the comparison variable (CBITS).

The implementation of the first block (VMULT1, VMULT2) may be adapted to perform in parallel at least two comparisons from at least two successive coefficients (C_O1, C_E1, C_O2, C_E2) of the array of coefficients with the interval of values.

The implementation of the first block (VMULT1, VMULT2) may include an implementation of at least two parallel branches (BRCH11, BRCH21, BRCH12, BRCH22) adapted to perform said two comparisons simultaneously, the implementation of each branch including: implementing a multiplier circuit (MLT11, MLT21, MLT12, MLT22) for performing a multiplication between one of said two successive coefficients (C_O1, C_E1, C_O2, C_E2) and a length (RGE) of said interval of values shifted by a given number of bits, this given number of bits being in particular between 0 and a number of bits used to define the length of said interval, implementing a comparator circuit (CMP11, CMP21, CMP12, CMP22) for comparing a result of the multiplication with a start value (LW) of the interval of values.

The implementation of the first block (VMULT1, VMULT2) may further include an implementation of a circuit (CUPDT1, CUPDT2) for updating the comparison variable to integrate into said comparison variable (CBITS) the results of the comparison performed by each comparator circuit.

The implementation of the dedicated circuit (HCW1, HCW2) may also include an implementation of a second block (TZC, LZC) for executing a state machine adapted to count the successive identical results stored in said comparison variable (CBITS) by analyzing the bits of said comparison variable (CBITS).

The results of each comparison performed by the first block (VMULT1) may be stored progressively on the right in the comparison variable (CBITS), and the state machine implemented by the second block (TZC) may be adapted to count the number of identical comparison results from the rightmost bits in the comparison variable (CBITS).

The results of each comparison performed by the first block (VMULT2) may be stored progressively on the left in the comparison variable (CBITS), and the state machine implemented by the second block (LZC) may be adapted to count the number of identical comparison results from the leftmost bits in the comparison variable (CBITS).

The execution of said computer program may lead to: implementing the first block (VMULT1, VMULT2) in order to carry out in parallel a comparison from each coefficient of said array of coefficients with said interval, the result of each comparison being stored in the comparison variable (CBITS), then implementing the second block (TZC, LZC), once all of the comparisons have performed, to count the successive identical results stored in said comparison variable (CBITS) by analyzing the bits of said comparison variable (CBITS), then calculating by the digital signal processor (DSP1, DSP2) a value (VAL) of the symbol associated with said array of coefficients on the basis of the number of successive identical results counted.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A system comprising:
one or more memories configured to store an array of coefficients and an interval of values;
a circuit configured to:
perform comparisons based on coefficients of the array of coefficients and the interval of values; and
count results of the comparisons that are identical and successive; and
a digital signal processor that performs arithmetic decoding by being configured to determine a value of a symbol associated with the array of coefficients based on the count of the identical and successive results.

2. The system of claim 1, wherein the circuit is configured to calculate a comparison variable that stores the results of the comparisons, wherein a result of each comparison corresponds to a bit of the comparison variable.

3. The system of claim 2, wherein the circuit is configured to perform at least two comparisons in parallel based on at least two successive coefficients of the array of coefficients and the range of values.

4. The system of claim 3, wherein the circuit comprises at least two parallel branches that allow the at least two comparisons to be performed in parallel, each parallel branch including:
a multiplier circuit configured to multiply a coefficient of the two successive coefficients and a length of the interval of values shifted by a given number of bits, wherein the given number of bits is between 0 and a number of bits used to define the length of the interval of values; and
a comparator circuit configured to compare a result of the multiplication with a start value of the interval of values.

5. The system of claim 4, wherein the circuit is configured to update the comparison variable based on the results of the comparison performed by each comparator circuit.

6. The system of claim 2, wherein the circuit is configured to implement a state machine that counts the successive identical results stored in the comparison variable by analyzing bits of the comparison variable.

7. The system of claim 6, wherein the results of each comparison performed by the first block are progressively stored in bits on the right of the comparison variable, and wherein the state machine is configured to count the number of successive identical comparison results starting from the rightmost bit of the comparison variable.

8. The system of claim 6, wherein the results of each comparison are progressively stored in bits on the left of the comparison variable, and wherein the state machine is configured to count the number of successive identical comparison results starting from the leftmost bit of the comparison variable.

9. The system of claim 6, wherein the digital signal processor includes the circuit and is further configured to:
perform, in parallel, a comparison of each coefficient of the array of coefficients with the interval of values, wherein a result of each comparison is stored in the comparison variable;
count successive identical results stored in the comparison variable by analyzing the bits of the comparison variable; and
calculate a value of the symbol associated with the array of coefficients based on the count of successive identical results.

10. One or more non-transitory computer-readable media storing instructions executable by one or more processors to perform actions, the actions comprising:
performing comparisons based on coefficients of an array of coefficients and an interval of values;
counting results of the comparisons that are identical and successive; and
determining a value of a symbol associated with the array of coefficients based on the count of identical and successive results.

11. The one or more non-transitory computer-readable media of claim 10, the actions further comprising:
calculating a comparison variable to store the results of the comparisons, the result of each comparison corresponding to one bit of the comparison variable.

12. The one or more non-transitory computer-readable media of claim 11, the actions further comprising:
performing, in parallel, at least two comparisons of at least two successive coefficients of the array of coefficients with the interval of values.

13. The one or more non-transitory computer-readable media of claim 12, wherein performing the at least two comparisons in parallel comprises:
multiplying a coefficient of the at least two successive coefficients and a length of the interval of values shifted by a given number of bits between 0 and a number of bits used to define the length of the interval of values;
comparing a result of the multiplication with a start value of the interval of values.

14. The one or more non-transitory computer-readable media of claim 13, wherein performing the at least two comparisons in parallel comprises:
updating the comparison variable based on the results of the at least two comparisons.

15. The one or more non-transitory computer-readable media of claim 11, wherein counting results of the comparisons that are identical and successive comprises:
executing a state machine adapted to count the successive identical results stored in the comparison variable by analyzing the bits of the comparison variable.

16. The one or more non-transitory computer-readable media of claim 15, wherein the result of each comparison is stored progressively on the right in the comparison variable, and wherein counting the successive identical results comprises counting the number of identical comparison results starting from the rightmost bit of the comparison variable.

17. The one or more non-transitory computer-readable media of claim 15, wherein the results of each comparison is stored progressively on the left in the comparison variable, and wherein counting the successive identical results comprises counting the number of successive identical comparison results starting from the leftmost bit of the comparison variable.

18. The one or more non-transitory computer-readable media of claim 11, the actions further comprising:
comparing, in parallel, the coefficients of the array of coefficients with the interval;
storing the result of each comparison in the comparison variable;
counting the successive identical results stored in the comparison variable by analyzing the bits of the comparison variable; and
calculating the value of the symbol associated with the array of coefficients based on the count of successive identical results.

19. A method comprising:
performing comparisons based on coefficients of an array of coefficients and an interval of values;
counting results of the comparisons that are identical and successive; and
determining a symbol associated with the array of coefficients based on the count of the results that are identical and successive.

20. The method of claim 19, wherein performing comparisons based on the coefficients of the array of coefficients and the interval of values comprises:
comparing, in parallel, at least two successive coefficients of the array of coefficients with the interval of values.
